(19) United States
(12) Patent Application Publication
(10) Pub. No.: US 2025/0116714 A1
(43) Pub. Date: Apr. 10, 2025

(54) VOLTAGE MONITORING DEVICE FOR AN ELECTRIC STACK, PARTICULARLY FOR A FUEL CELL STACK

(71) Applicants: Stefan MUNTHE, Västra Frölunda (SE); Johan FLINK, Göteborg (SE); Robin VELÉN, Hovas (SE); POWERCELL SWEDEN AB, Göteborg (SE)

(72) Inventors: Stefan MUNTHE, Västra Frölunda (SE); Johan FLINK, Göteborg (SE); Robin VELÉN, Hovas (SE)

(21) Appl. No.: 18/833,219

(22) PCT Filed: Feb. 6, 2023
(86) PCT No.: PCT/SE2023/050095

§ 371 Date: Jul. 25, 2024

(30) Foreign Application Priority Data
Feb. 10, 2022 (SE) 2250131-6

(51) Int. Cl. G01R 31/385; H01M 8/04537

(52) U.S. Cl. CPC G01R 31/385; H01M 8/04559

(57) ABSTRACT

Disclosed is an electric cell stack comprising a plurality of electric plates sandwiching insulation layers, wherein at least one of the plurality of electric plates a voltage monitoring element for monitoring a voltage of said electric plate is arranged, wherein said at least one electric plate at which the electric voltage monitoring element is arranged has at least one through hole, wherein at and/or in the through hole the voltage monitoring element is arranged.

### DESCRIPTION

The present invention relates to an electric cell stack according to claim 1 and in particular to a fuel cell stack.

Usually, an electric cell stack comprises a plurality of stacked electric plates which are separated from each other by insulating layers.

In the special case of a fuel cell stack, the electric plates are bipolar plates and the insulating layers are multi-layer membrane electrode assemblies. The bipolar plates themselves are a combination of an anode plate and a cathode plate which are fixed to each other, wherein the bipolar plates are then separated, or with other words sandwiched, by the membrane electrode assemblies. The cathode and anodes plate which form the bipolar plates are usually electrically conducting metal or graphite plates, so called flow field plates, having a flow field for the reactants at one side and a flow field for a cooling fluid on the other side. In the assembled state of the membrane electrode assembly the flow field plates are placed on top of each other in such a way that the cooling fluid flow fields are facing each other and the reactant fluid flow fields face the sandwiching membrane electrode assemblies. The electric current produced by the membrane electrode assemblies during operation of the fuel cell stack results in a voltage potential difference between the bipolar plate assemblies.

During the operation of the electric stack, the voltage produced by the stacked cells needs to be monitored for determining whether the stack is operating within its intended operation parameters. For that, each electric plate is usually equipped with voltage monitoring elements, which are fixed to the electric plate and are provided with wires for connecting the voltage monitoring elements to an external voltage monitoring controller, which monitors and controls the operation of the stack.

Thereby, it is known to use the wires as the voltage monitoring elements, by soldering or welding the wires directly the electric plate. In the field of fuel cell stacks, it is also known to use pin connections, where the pins are inserted between the plates of the bipolar plates, where they are fixed by friction force or press-fit.

However, placing and fixing the wires into the electric cell stack is cumbersome and time-consuming, which makes the stacking process inefficient and slow. Additionally, the known fixation methods are also prone to failure as the wires and pins may come loose from the plates or the wires and pins are misplaced so that they cause failures in the stack.

Additionally, due to the usually tight stacking of the electric plates and associated insulating layer, the electric cell stack lacks the space to fit voltage monitoring elements, which might be easier to mount.

It is therefore object of the present invention to provide a voltage monitoring element that can be implemented into the electric cell stack, and in particular in the fuel cell stack, in a more efficient and reliable way.

This object is solved by an electric cell stack according to claim 1.

In the following, a fuel cell stack is provided which comprises a plurality of electric plates sandwiching insulation layer, wherein at at least one of the plurality of electric plates a voltage monitoring element for monitoring a voltage of said electric plate is arranged. More particularly, the voltage monitoring connector may be molded, preferably injection molded.

In order to implement the voltage monitoring element more efficiently said at least electric plate at which the electric voltage monitoring element is arranged has at least one through hole, wherein at and/or in the through hole the voltage monitoring element is arranged. Thereby, the through hole provides an additional space which allows for accommodating the voltage monitoring element.

It should be noted that in general, in this application, the term “electric plate” does not necessarily refer to a rigid electric plate. Also, a flexible layer-like electric element (anode or cathode) may be named as electric plate in this application.

Additionally, the electric cell stack may be a fuel cell stack, wherein the electric plate is a bipolar plate consisting of an anode plate and a cathode plate, which are fixed to each other. Further in that case, the insulating layers are multilayer membrane electrode assemblies. The bipolar plates are usually rigid metal or graphite plates which are provided with flow field structures for providing and distributing reactant and/or coolant to the bipolar plate and/or to the adjacent membrane electrode assemblies.

According to a preferred embodiment, the voltage monitoring element is made from an electrically insulting material and is equipped with an electrical contact element made from an electrically conducting material, which is arranged at a surface of the voltage monitoring element and which is adapted to be in contact with the electric plate. The known pins or wires are quite small so that fixing the voltage monitoring elements to the plates is a very delicate work. Further, there is a high risk of misplacing the pins, which can result in a damage of the stack element and eventually in a failure of the whole stack. By providing a voltage monitoring element which is mainly made from an electrically insulating material and is only at special locations equipped with electrically conducting elements allows for a simpler and simplified handling and mounting of the voltage monitoring element. It should be noted that the electric contact elements is usually equipped with an integrated wire for the known connection with an external voltage motoring controller.

According to a further preferred embodiment, the voltage monitoring connector has a base plate and a protruding portion, wherein the protruding portion is recessed from the base plate so that a step is formed between the base plate and the protruding portion. Thereby, an easy-to-handle element is provided which can be arranged at the electric plate and in the through hole in a time efficient way.

Thereby it is advantageous that a height h of the voltage monitoring element is designed to be less than a thickness D_{EP} of the electric plate (2): h<D_{EP}. In particularly in the above-mentioned case of a voltage monitoring element being provided with a base plate and protruding portion, it is further preferred that a height hₚ of the protruding portion of the voltage monitoring element is designed to be less than a thickness D_{EP} of the electric plate (2): hₚ<D_{EP}. This allows for a voltage monitoring element that is flush with the electric plate on at least one side. Such a voltage monitoring element does not require any additional space as it is at least partly fully accommodated in the electric plate.

According to a further advantageous embodiment, the voltage monitoring element has, at the opposite side of the protruding portion, at the base plate a recess which is dimensioned to accommodate the protruding portion of an adjacent voltage monitoring element, so that one voltage monitoring element is adapted to be stacked on a further voltage monitoring element. Thereby even if the voltage monitoring element is extending over the electric plate, e.g. after compression of the stack, the exceeding part does not negatively interfere with the overall dimensions of the stack.

To the contrary, in case such a recess is provided it might also be possible to provide a voltage monitoring element, wherein a height hₚ of the protruding portion of the voltage monitoring element is designed to be greater than a thickness D_{EP} of the electric plate: hₚ>D_{EP}, and wherein a depth hᵣ of the recess is adapted to accommodate that part of the protruding portion of the voltage monitoring element which extends over the electric plate. Thereby, the voltage monitoring element can also be used as alignment feature for the components of the stack, as the stacked voltage monitoring elements also define a certain orientation of the electric cell stack components to each other.

According to a further preferred embodiment, a diameter of the base plate is designed to be larger than a diameter of the through hole so that a surface of the step at least partially abuts a surface of the electric plate and the protruding portion extends through the through hole of the electric plate. This allows for a secure mounting of the voltage monitoring element at and in the through hole of the electric plate.

It is further preferred if the voltage monitoring element further comprises a cover portion, wherein a diameter of the cover portion is larger than a diameter of the through hole so that the voltage monitoring element is fixed to the electric plate. This allows for a connection and fixation of the cover element on both sides of the plates. The cover element could be for example realized as snapping elements which extend over the rim of the electric plate after having been inserted through the through hole, so that the voltage monitoring element is fixed to the electric plate.

Alternatively of additionally, the cover portion may be a separate element which is adapted to interact with the protruding portion of the voltage monitoring element for fixing the voltage monitoring element to the electric plate. Thereby, it is particularly preferred that the cover element has a recess which is designed to accommodate the protruding portion in such a way that a connection between cover element is provided by form fit or force fit. E.g. the cover element can be pressed and/or clicked onto the protruding portion.

For also providing the internal alignment feature, it is possible that the cover element further comprises a protrusion on the opposite side to its side facing the electric plate, which allows for an interaction with an adjacent voltage monitoring element, particularly for an interaction with the recess of the adjacent voltage monitoring element. It is further possible that the cover element has an annular form which interacts with the protruding portion in a friction fit manner, so that the protruding portion may extend through the annular cover element and be accommodated in the recess of the adjacent voltage monitoring element.

The cover element thereby ensures that the voltage monitoring element remains fixed to the electric plate even if the electric plate is not arranged in the stack. This also allows for pre-mounting of the voltage monitoring element at the electric plate before stacking.

According to a further preferred embodiment, the electrical contact element is arranged at a surface of the voltage monitoring element. Preferably, the electrical contact element is arranged at the base plate, preferably at the step, and/or at the protruding portion and/or at the cover portion in such a way that the electric contact element is in contact with the electric plate.

As mentioned above, the voltage monitoring element may be made of an electrically isolating material, preferably a plastic material, and the electric contact element may be made from an electrical conducting material. Thereby a metal such as copper, aluminum, silver, gold, tin or the like is preferred. When deciding for a certain material for the electric contact element, the material of the bipolar plate should be taken into account for avoiding creating galvanic issues. For a stainless steel bipolar plate, e.g. a coated copper material such as a gold plated copper, is preferred. Further, the electric contact element may be a resilient element, preferably the electric contact element is resiliently shaped. For example, the electric contact element may be shaped as a spring.

As mentioned above, the electric contact element is connected with a wire for connection with an external voltage monitoring controller. It is also possible that the electric contact element is made from the wire or a wire-form material.

According to a further embodiment, the voltage monitoring element is made from the same material as the insulating layer or may even be an integral part of the insulating layer. In particular, the voltage monitoring element may be made from a subgasket material of a membrane electrode assembly or may be an integral part of the membrane electrode assembly. This allows for a space-saving accommodation of the voltage monitoring connector in the electric cell stack or the fuel cell stack, respectively.

According to a further preferred embodiment, the electric plate further comprises a flow field for distributing reactant over the electric plate. Thereby, the flow field may be designed as protruding structure protruding from a basis of the plate. Alternatively, the plate may also have other protruding structures, e.g. a bead seal, which also protrudes from the basis of the electric plate. These protruding structures are common for fuel cells, where the bipolar plates are designed to distribute reactant to the membrane electrode assembly.

In case the electric plate has at least one protruding structure, e.g. a bead seal or flow field, which protrudes from the basis of the electric plate in direction of the adjacent insulating layer, it is further preferred that a height h_{b} of the base plate of the voltage monitoring element is designed to resemble, preferably to be less than, a protruding height D_{PS} of the protruding structure over the basis of the electric plate: h_{b}≈D_{PS}, preferably h_{b}<D_{PS}. This ensures that the voltage monitoring element can be placed within the electric cell stack without further space requirement. This further allows to implement the voltage monitoring element within the electric cell stack without increase the size of the electric cell stack.

In case the electric plate has at least one protruding structure, e.g. a bead seal or flow field, which protrudes from the basis of the electric plate in direction of the adjacent insulating layer, it is further preferred that also a height h_{c} of the cover portion of the voltage monitoring element is designed to resemble, preferably to be less than, a protruding height D_{PS} of the protruding structure over the basis of the electric plate: h_{c}≈D_{PS}, preferably h_{c}<D_{PS}. This also ensures that the voltage monitoring element can be placed within the electric cell stack without further space requirement and without increasing the size of the electric cell stack.

According to a further preferred embodiment, the protruding portion of the voltage monitoring element may have a first part and a second part, wherein the second part is recessed to the first part, thereby forming a further step between the first and the second part of the protruding portion, and wherein the further step is provided with an electrical contact element which is adapted to contact a electric plate. Thereby it is further preferred that both steps, the step between base plate and first part and the step between first and second part are equipped with electrical contact elements. This allows for electrically connecting not only a single electric plate but two electric plates which are arranged adjacent to each other, which further reduces the time requirements during stacking and simplifies the stacking process as only every third plate needs to be equipped with a separate voltage monitoring element.

Thereby it is further preferred that the electric plate has a first and a second through hole at and/in which a voltage monitoring element is accommodated, wherein a size and/or shape of the first and second through hole differ from each other. This allows, in particular, for an advantageous interaction between the stepped voltage monitoring element and the two adjacent electric plates.

Thereby it is further advantageous if the size of the first part of the protruding portion is adapted to the size and/or shape of the first through hole and the size of the second part of the protruding portion is adapted to the size and/or shape of the second through hole. This allows for a fail-safe arrangement of voltage monitoring element and through holes/electric plates.

It is further preferred that adjacent electric plates and corresponding first and second through holes are arranged in such a way that the first through hole of one electric plate is aligned with the second through hole of the adjacent electric plate. Thereby, it is further preferred, if the electric plates are symmetric concerning a rotation of 180° around the surface normal of the electric plate. In case the electric plate is a bipolar plate it is preferred that the bipolar plates are symmetrical concerning a rotation of 180° around the surface normal of the cathode or anode side. Thereby, rotation of each second electric plate of the stack by 180° results in an automatic arrangement of alternating first and second through holes. Besides a simplified manufacturing, stacking and alignment, as only one set of electric plates has to be produced, this allows also for compensating manufacturing tolerances, which would lead to an uneven size of the stack.

According to a further preferred embodiment, the electric cell stack has at least two, preferably three, electric plates which are stacked, wherein the heights hₚ₁, hₚ₂ of the first and second parts are designed such that the electrical contact element which is arranged at the first step is in contact with the first electric plate, and the electrical contact element which is arranged at the further step between the first and the second part is in contact with the second electric plate. Further, the second part may protrude into an opening in the second electric plate but does not exceed over the second electric plate. Alternatively, the second part exceeds over the second electric plate and may be adapted to be accommodated in a recess of an adjacent voltage monitoring connector being arranged at the third bipolar plate. This allows to implement the voltage monitoring element within the electric cell stack without increasing the size of the electric cell stack.

It goes without saying that the voltage monitoring element may have a plurality of further steps, wherein each step is equipped with an electric connector to be in contact with a respective electric plate.

Further preferred embodiments are defined in the dependent claims as well as in the description and the figures. Thereby, elements described or shown in combination with other elements may be present alone or in combination with other elements without departing from the scope of protection.

In the following, preferred embodiments of the invention are described in relation to the drawings, wherein the drawings are exemplarily only, and are not intended to limit the scope of protection. The scope of protection is defined by the accompanied claims, only.

The figures show:

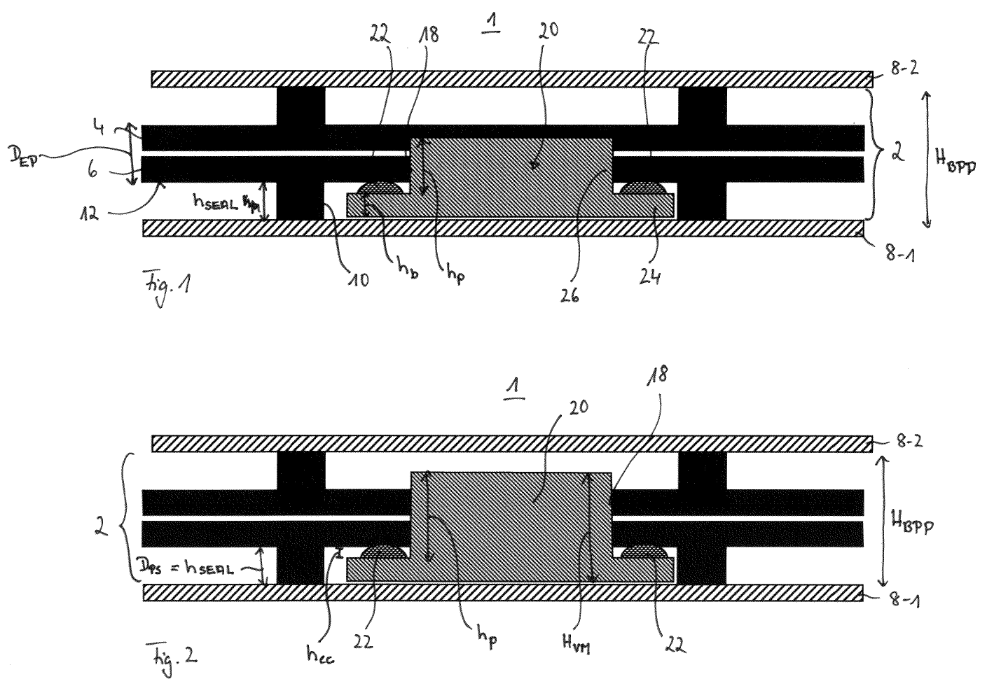

FIG. 1: a cross section through a fuel cell stack according to a first exemplary embodiment;

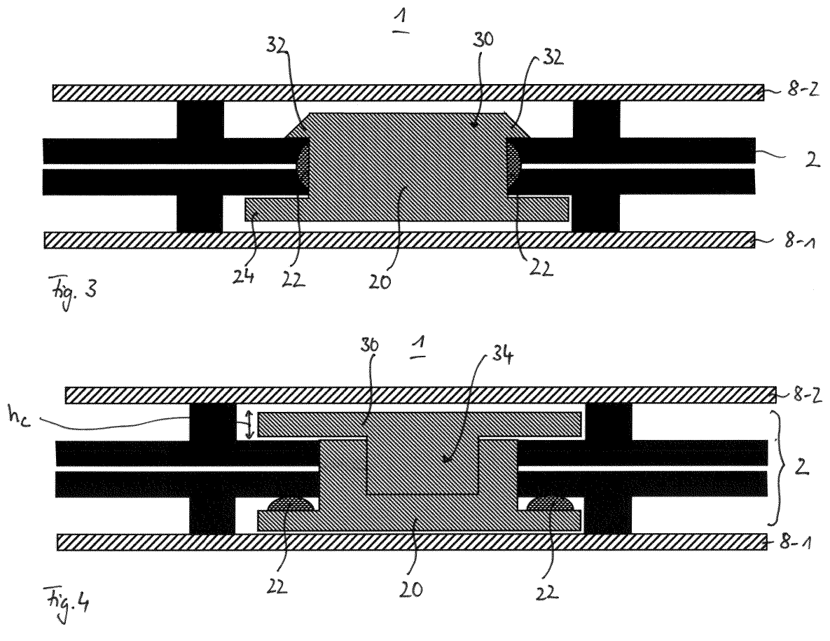

FIG. 2: a cross section through a fuel cell stack according to a second exemplary embodiment;

FIG. 3: a cross section through a fuel cell stack according to a third exemplary embodiment;

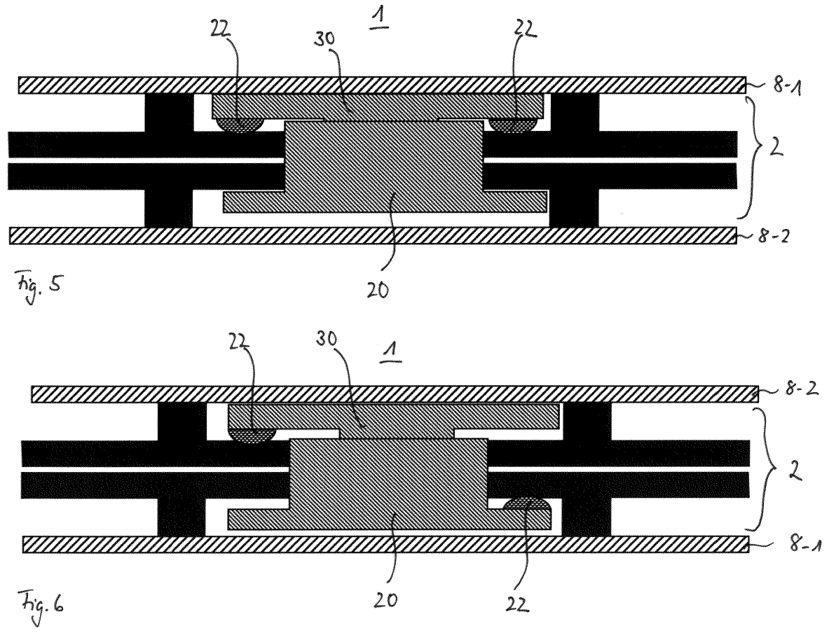

FIG. 4: a cross section through a fuel cell stack according to a fourth exemplary embodiment;

FIG. 5: a cross section through a fuel cell stack according to a fifth exemplary embodiment;

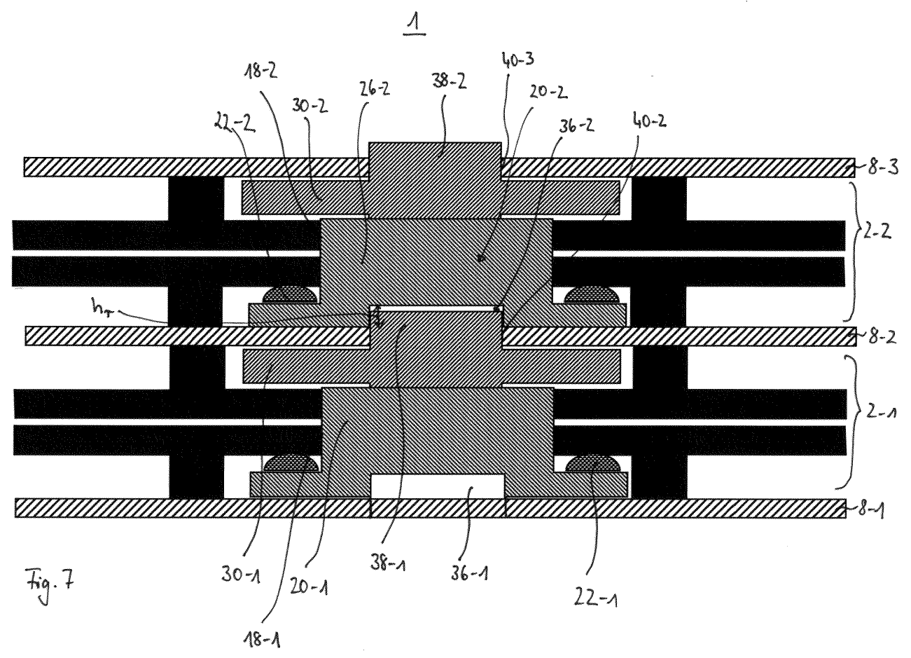

FIG. 6: a cross section through a fuel cell stack according to a sixth exemplary embodiment;

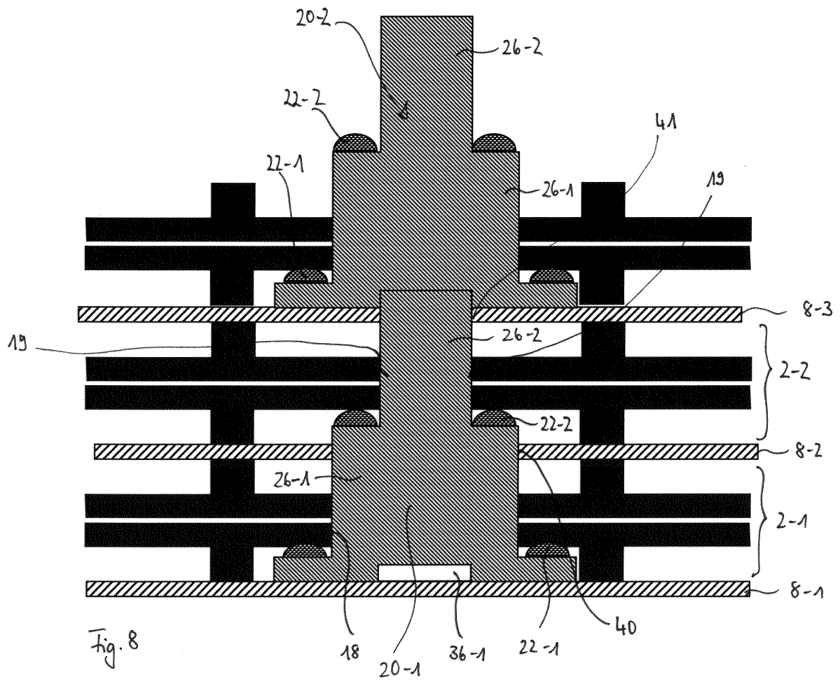

FIG. 7: a cross section through a fuel cell stack according to a seventh exemplary embodiment;

FIG. 8: a cross section through a fuel cell stack according to an eighth exemplary embodiment; and

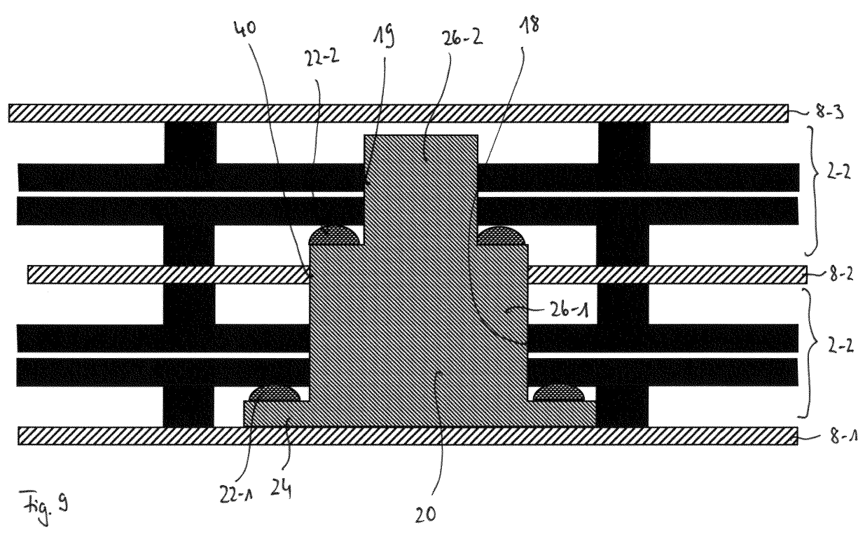

FIG. 9: a cross section through a fuel cell stack according to a nineth exemplary embodiment.

In the following same or similar functioning elements are indicated with the same reference numerals.

In the following, the principle of the invention is described for the case of a fuel cell stack. However, the principle can be likewise applied to any other kind of electric cell or electric cell stack. Further, features illustrated with regard to one embodiment may also be included alone or in combination in other embodiments.

The FIGS. 1 to 9 show partly a fuel cell stack 1, with at least one bipolar plate 2, with an anode plate 4 and a cathode plate 6. Each bipolar plate 2 is sandwiched by a first membrane electrode assembly 8-1 and second membrane electrode assembly 8-2. The membrane electrode assembly 8 itself is usually a multi-layer membrane electrode assembly, but is, for the sake of simplicity, only illustrated as single layer in the Figs. It is further illustrated that the bipolar plates 2 have protruding structures 10, 14, e.g. bead seals or channel like structures of a flow field, which protrude over a basis 12 (anode side), 16 (cathode side) of the bipolar plate 2, wherein basis 12 and basis 16 define a thickness of the electric plate D_{EP}, and the protruding structure defines a thickness D_{PS} or a height h_{SEAL}, respectively.

The FIGS. 1 to 9 show various preferred embodiments of a voltage monitoring element 20. Each voltage monitoring element is equipped with at least one electric contact element 22 having a height h_{ec}, which is arranged at a surface of the voltage monitoring element 20 and which is adapted to be in contact with the bipolar plate 2. For the sake of simplicity the electric contact element 22 is only schematically illustrated in the Figures. It should be noted that each electric contact element 22 is usually equipped with a wire (not shown) for a connection to an external voltage monitoring controller.

For mounting the voltage monitoring element 20 to the bipolar plate 2, the bipolar plate 2 is provided with through holes 18 into which and through which the voltage monitoring element 22 may be inserted.

Further, in the illustrated embodiments, the voltage monitoring element 20 is made from an electrically insulting material, whereas the electrical contact element 22 is made from an electrically conducting material. The electrical insulating material may be a plastic material, and the voltage monitoring element 20 may be molded or injection molded. The electric contact element 22 may be made from copper. Also, the electric contact element 22 may be a resilient element, preferably the electric contact element is resiliently shaped 22. For example, the electric contact element 22 may be shaped as a spring, which is schematically illustrated by the half-circular shape of the electric contact element in the FIGS. 1 to 9.

The voltage monitoring elements 20 as illustrated in FIGS. 1 to 9, have a base plate 24 with a height h_{b} and a protruding portion 26 with a height hₚ. The protruding portion 26 is recessed from the base plate 24 so that a step 28 is formed between the base plate 24 and the protruding portion 28. Moreover, the electrical contact element 22 is arranged at the base plate 24, and in particular at the step 28, so that the electric contact element 22 is in contact with the respective bipolar plate 2.

As can be further seen from the FIG. 1, the height h_{b} of the base plate 24 and the height h_{ec} of the electric contact element 22 is designed so that the overall height h_{b}+h_{ec} of the base plate 24 and of the electric contact element 22 is less than a height h_{SEAL}(=D_{PS}) of the protruding portion 14, e.g. of the bead seal, of the bipolar plate 2: h_{SEAL}>h_{b}+h_{c}.

The height of the protruding portion hₚ of the voltage monitoring element 20 may be designed so that the voltage monitoring element 20 does not protrude through both anode and cathode plates 4, 6 (hₚ<D_{EP}) (see FIG. 1), or may be designed so that the voltage monitoring element 20 protrudes through both anode and cathode plates, 4, 6 (hₚ>D_{EP}) (see FIG. 2). However, in both cases an overall height Hv of the voltage monitoring element 20 as such does not protrude over the overall height H_{BPP} of the bipolar plate 2 at any location: H_{BPP}>Hv, wherein H_{BPP}=D_{EP}+h_{SEAL}.

As can be seen in the embodiment illustrated in FIG. 3, the electric contact elements 22 may also be arranged at different locations, than the step 28, e.g. at the side faces of the protruding portion 28, as illustrated.

As ca be further seen in FIG. 3 as well as in FIGS. 4 to 8, the voltage monitoring element 20 may be equipped with a cover portion 30 having a height h_{c}. The cover portion 30 is designed to fix the voltage monitoring element 20 to the bipolar plate 2. This allows for a pre-mounting of the voltage monitoring element 20 before stacking of the fuel cell stack.

In the embodiment of FIG. 3, the cover portion 30 is an integral part of the voltage monitoring element 20, and may be designed as hooks 32 which are adapted to be snapped over a rim of the through hole 18 of the bipolar plate 2.

Alternatively, the cover portion 30 may be designed as separate element which may interact with the protruding portion 26 of the voltage monitoring element 20 as illustrated in FIGS. 4 to 6. Thereby the cover potion 30 as illustrated e.g. in FIG. 4 may be equipped with a connection section 34.—in the illustrated embodiments the connection section 34 is designed as protrusion which may be accommodated within a recess (not illustrated) having a depth hᵣ (also not illustrated) provided in the protruding portion 26 of the voltage monitoring element 20 for securely fixing the cover portion 30 to the protruding portion 26. Of course, other connection possibilities are likewise possible. E.g. the cover portion 30 may also be equipped with a recess having a depth hᵣ which interacts with the protruding portion 26.

In all cases, it is preferred that, the cover portion 30 and the protruding portion 26 interact in such a way that the cover portion 30 and protruding portion 26 are fixed to each other, e.g. by force fit, friction fit etc. For that, further elements, like snapping elements may be provided at the protruding portion 26 or at the cover portion 30. It is also possible that cover portion 30 and protruding portion 26 are bonded to each other e.g. by gluing or welding etc.

In case the voltage monitoring element 20 is provided with a cover portion 30 it is of course also possible to arrange the electric contact elements at the cover portion (see e.g FIG. 5) or at both the cover portion 30 and the base portion 24 (see e.g. FIG. 6) or any other surface of the voltage monitoring element 20.

As mentioned above, each bipolar plate 2 has at least one opening 18 which is adapted to accommodate the protruding portion 26 of the voltage monitoring element 20. The voltage monitoring element 20 is adapted to be fixed to the bipolar plate 2. In a not illustrated embodiment, the voltage monitoring element 20 may also be adapted to be fixed to or be an integral part of the multilayer membrane electrode assembly 8 of the fuel cell stack 1, in particular may be part of a subgasket surrounding the multilayer membrane electrode assembly 8

Besides its function as voltage monitoring element, the voltage monitoring element 20 may also be used as stacking and alignment assistance. For that, the voltage monitoring element may be equipped with structures which allow for an interaction of one voltage monitoring element 20-1 with an adjacent voltage monitoring element 20-2. FIGS. 7 to 10 illustrate various embodiments for voltage monitoring elements 20-1, 20-2 with additional alignment features.

As illustrated int FIGS. 7 to 9, in case such a stacking and alignment assistance shall be provided it is preferred that also the membrane electrode assembly 8 is provided with a through hole 40, through which a part or portion of the voltage monitoring element 20-1 may extend for an interaction with an adjacent voltage monitoring element 20-2.

Further, for the interaction between two adjacent voltage monitoring elements 20-1, 20-2, and as illustrated in FIGS. 7 and 8, it is further preferred that the voltage monitoring element 20 is further equipped with a recess 36 at the opposite side of the protruding portion. Thereby it is further preferred that a size and or shape and/or depth hᵣ of the recess is adapted to accommodate the protruding portion 26 of the adjacent voltage monitoring element. This allows for a stacking of the voltage monitoring elements 20-1 20-2 on top of each other which automatically results in an alignment of the bipolar plates 2 and the interlaying membrane electrode assemblies 8.

In FIG. 7 a first embodiment is illustrated, wherein the cover portion 30 as described with reference to FIGS. 4 to 6 above, is at its membrane electrode assembly facing side equipped with a projecting portion 38, which extends through the through hole 40 provided at the membrane electrode assembly 8.

This projection portion 38-1 is accommodated in the recess 36-2 of the adjacent voltage monitoring element 20-2, which allows for an alignment of bipolar plate 2-1 in relation to bipolar plate 2-2, as well as of the membrane electrode assemblies 8 to the bipolar plates 2.

FIG. 2 shows a fuel cell stack 1 according to a second exemplary embodiment. The fuel cell stack 1 of FIG. 2 differs from the fuel cell stack 1 of FIG. 1 in that the protruding portion 10 of the voltage monitoring connector 6 has a first part 17 and a second part 18, wherein the second part 18 is recessed to the first part 17, thereby forming a further step 20 between the first 17 and the second part 18 of the protruding portion 10.

As can be further seen in this embodiment, the through holes 18 and 40 of bipolar plate 2 and membrane electrode assembly 8, respectively, may be differently shaped and adapted to the protruding portion 26 and the projecting portion 38, respectively. This also allows for a certain orientation of the bipolar plate 2 and membrane electrode assembly 8 in relation to the voltage monitoring element 20 and therefore also to each other.

In the embodiments of FIGS. 8 and 9, the voltage monitoring element 20 extends over a single bipolar plate 2 but over two bipolar plates 2-1 and 2-2. Thereby, the protruding portion 26 of the voltage monitoring element 20 comprises a first part 26-1 and a second part 26-2, which are recessed to each other and form a further step 27. As can be further seen, the voltage monitoring element 22 has a first electric contact element 22-1 at the base step, and, at the further step 27, a second electric contact element 22-2, wherein the first electric contact element is adapted to contact the first bipolar plate 2-1 and the second electric contact element 22-2 is adapted to contact the second bipolar plate 2-2.

Further, each bipolar plate 2 has a first opening 18 which is adapted to accommodate the first part 26-2 of the protruding portion 26 of the voltage monitoring element 20 and a second opening 19 which is adapted to accommodate the second part 26-2 of the protruding portion 26 of the voltage monitoring element 20. The first and second bipolar plates 2-1, 2-2 are arranged in such a way that the first opening 18 of the first bipolar plate 2-1 is aligned with the second opening 19 of the second bipolar plate 2-2.

Further, as illustrated, the second part 26-1 of the protruding portion 26 may be accommodated in the recess 36-2 of the adjacent voltage monitoring element 20-2, which allows for the automatic alignment of the bipolar plate and membrane electrode assemblies 8. It should be further noted that in this embodiment, the membrane electrode assembly 8 is also equipped with two through hole with different sizes. Thus, membrane electrode assembly 8-2 has a through hole 40, having a first size and membrane electrode assembly 8-3 has a through hole 41, which differ from the size of through hole 40. As with the bipolar plate the size and shape of the through holes may be adapted to the size and shape of the first and/or second part 26-1, 26-2 of the protruding portion 26.

FIG. 9 illustrates an embodiment, wherein the voltage monitoring element 20 provides an electrical contact to two plates but not interaction to an adjacent voltage monitoring element 20-2. In this case, only every second membrane electrode assembly 8-2; 8-4 . . . need to be equipped with a through hole 40 through which the voltage monitoring element 20 may protrude. Also in this case, an alignment of the first and second bipolar plate 2-1, 2-2 is possible as the bipolar plate are still provided with differently sized through holes 18, 19 and the voltage monitoring element 20 provides an alignment of the plates to each other due to the interaction between the size of the protruding potions 26-1, 26-2 and the corresponding through holes 18, 19 of the bipolar plates 2-1, 2-2. This voltage monitoring element 20 is also able to electrically contact two bipolar plates 2-1, 2-2 as on both steps electric contact elements 22-1, 22-2 are arranged.

It should be noted that even if, in FIGS. 4 to 9, the electric contact elements 22 are arranged at the steps it is also possible that the electric contact elements are arranged at other appropriate surfaces of the voltage monitoring element 20 or the of the cover portion 30.

In summary, the disclosed voltage monitoring element allows for simple and reliable arrangement of the voltage monitoring elements at the bipolar plates. Further, any misplacement of the electric contacting element can be avoided, whereby also any damage of the fuel cell stack due to the misplacement may be avoided.

### Reference Numerals

1 Fuel cell stack
2 Bipolar plate
4 anode plate
6 cathode plate
8 membrane electrode assembly
10 protruding portion (Bead seal) of bipolar plate
12 basis of bipolar plate
18; 19 Through hole through bipolar plate
20 voltage monitoring element
22 electric contact element
24 Base plate
26 Protruding portion
28 step
30 cover portion
32 hooks
34 connection element cover element
36 recess
38 projection portion cover element
40, 41 through hole membrane electrode assembly
h_{b} Height of the base plate
hₚ Height of the protruding portion
h_{c} height of the cover portion
h_{ec} height of the electric contact element
hᵣ depth of the recess
h_{SEAL}=D_{PS} Height of protruding portion of the bipolar plate
D_{EP} height of the basis of the bipolar plate
H_{VM} Overall height of voltage monitoring element
H_{BPP} Overall height of the bipolar plate

1. Electric cell stack comprising a plurality of electric plates sandwiching insulation layers, wherein at at least one of the plurality of electric plates a voltage monitoring element for monitoring a voltage of said electric plate is arranged,
wherein said at least one electric plate at which the electric voltage monitoring element is arranged has at least one through hole, wherein at and/or in the through hole the voltage monitoring element is arranged.

2. Electric cell stack according to claim 1, wherein the voltage monitoring element is made from an electrically insulting material and is equipped with an electrical contact element made form an electrically conducting material, which is arranged at a surface of the voltage monitoring element and which is adapted to be in contact with the electric plate.

3. Electric cell stack according to claim 1, wherein the voltage monitoring element has a base plate and a protruding portion, wherein the protruding portion is recessed from the base plate portion so that a step is formed between the base plate and the protruding portion.

4. Electric cell stack according to claim 3, wherein a height hₚ of the protruding portion of the voltage monitoring element is designed to be less than a thickness D_{EP} of the electric plate: hₚ<D_{EP}.

5. Electric cell stack according to claim 3, wherein the voltage monitoring element has, at the opposite side of the protruding portion, at the base plate a recess, which is dimensioned to accommodate the protruding portion of an adjacent voltage monitoring element, so that one voltage monitoring element is adapted to be stacked on a further voltage monitoring element.

6. Electric cell stack according to claim 5, wherein a height hₚ of the protruding portion of the voltage monitoring element is designed to be greater than a thickness D_{EP} of the electric plate: hₚ>D_{EP}, and wherein a depth hᵣ of the recess is adapted to accommodate that part of the protruding portion of the voltage monitoring connector which extends over the electric plate.

7. Electric cell stack according to claim 3, wherein a diameter of the base plate is designed to be larger than a diameter of the through hole so that a surface of the step at least partially abuts a surface of the electric plate and the protruding portion extends through the through hole of the electric plate.

8. Electric cell stack according to claim 3, wherein the voltage monitoring element further comprises a cover portion, wherein a diameter of the cover portion is larger than a diameter of the through hole so that the voltage monitoring element is fixed to the electric plate.

9. Electric cell stack according to claim 8, wherein the cover portion is a separate element which is adapted to interact with the protruding portion of the voltage monitoring element for fixing the voltage monitoring element to the electric plate.

10. Electric cell stack according to claim 2, wherein the electrical contact element of the voltage monitoring element is arranged at the base plate, preferably at the step, at the protruding portion, and/or at the cover portion in such a way that the electric contact element is in contact with the electric plate.

11. Electric cell stack according to claim 3, wherein the electric plate has at least one protruding structure which protrudes from a basis of the electric plate in direction to the adjacent insulating layer with a height D_{PS}, and wherein a height h_{b} of the base plate of the voltage monitoring element is designed to be equal or less than the height D_{PS} of the protruding structure: h_{b}≤D_{PS}, preferably h_{b}<D_{PS}.

12. Electric cell stack according to claim 6, wherein the electric plate has at least one protruding structure which protrudes from a basis of the electric plate in direction to the adjacent insulating layer with a height D_{PS}, and wherein a height h_{c} of the cover portion of the voltage monitoring element is designed to be equal or less than the height D_{PS} of the protruding structure: h_{c}≤D_{PS}, preferably h_{c}<D_{PS}.

13. Electric cell stack according to claim 3, wherein the protruding portion of the voltage monitoring element has a first part and a second part, wherein the second part is recessed to the first part, thereby forming a further step between the first and the second part of the protruding portion, and wherein preferably both steps are provided with an electrical contact elements which are each adapted to contact a electric plate.

14. Electric cell stack according to claim 1, wherein the electric plate has a first and a second through hole at and/in which a voltage monitoring element is accommodated, wherein a size and/or shape of the first and second through hole differ from each other.
